(19) United States
(12) Patent Application Publication
(10) Pub. No.: US 2026/0164785 A1
(43) Pub. Date: Jun. 11, 2026

(54) SEMICONDUCTOR DEVICE INCLUDING SILICON NITRIDE ISOLATOR AND METHOD FOR FABRICATING THE SAME

(71) Applicant: SAMSUNG ELECTRONICS CO.,LTD., Suwon-si (KR)

(72) Inventors: Il Min LEE, Suwon-si (KR); Seok Ju KIM, Suwon-si (KR); Ji Eun KIM, Suwon-si (KR); Jeong Min LEE, Suwon-si (KR); Ju Hyeok JUNG, Suwon-si (KR)

(73) Assignee: SAMSUNG ELECTRONICS CO., LTD., Suwon-si (KR)

(21) Appl. No.: 19/265,290

(22) Filed: Jul. 10, 2025

(30) Foreign Application Priority Data
Dec. 11, 2024 (KR) 10-2024-0183343

(51) Int. Cl. H10D 84/85; H10D 84/01

(52) U.S. Cl. CPC H10D 84/851; H10D 84/0188

(57) ABSTRACT

Provided is a semiconductor device and method of manufacturing same, the semiconductor device including: a protruding pattern extending in a first direction; a first channel pattern spaced apart from the protruding pattern in a second direction; a channel isolation pattern between the protruding pattern and the first channel pattern, wherein the channel isolation pattern includes silicon nitride and is in contact with the protruding pattern; a field insulating film on a sidewall of the protruding pattern; a gate electrode on an upper surface of the field insulating film and extending in a third direction; a source/drain pattern on at least one side of the gate electrode and connected to the first channel pattern; and a field capping film between the upper surface of the field insulating film and a bottom surface of the gate electrode, the field capping film including silicon (Si) and nitrogen (N).

### CROSS-REFERENCE TO RELATED APPLICATION

This application claims priority from Korean Patent Application No. 10-2024-0183343, filed on Dec. 11, 2024 in the Korean Intellectual Property Office, the contents of which are herein incorporated by reference in its entirety.

### BACKGROUND

### 1. Field

The present disclosure relates to a semiconductor device and a method for fabricating the same.

### 2. Description of the Related Art

As one of the scaling techniques for increasing the density of semiconductor devices, multi-gate transistors have been proposed, in which fin-shaped silicon bodies are formed on a substrate, and gates are formed on the surfaces of the silicon bodies.

Since such multi-gate transistors utilize three-dimensional (3D) channels, scaling can be readily achieved. Additionally, the current control capability can be improved without increasing the gate length of the multi-gate transistors. Furthermore, short channel effects (SCE), where the channel region's potential is influenced by the drain voltage, can be effectively suppressed.

Recently, a technique has been increasingly employed in which a layer including a stress material is formed within a silicon body of a fin shape to increase the carrier mobility in the channel region of a semiconductor device.

### SUMMARY

Provided is a semiconductor device with improved operational characteristics and reliability.

Further provided is a method for fabricating a semiconductor device with improved operational characteristics and reliability.

According to an aspect of the disclosure, a semiconductor device includes: a protruding pattern extending in a first direction; a first channel pattern spaced apart from the protruding pattern in a second direction; a channel isolation pattern between the protruding pattern and the first channel pattern, wherein the channel isolation pattern includes silicon nitride and is in contact with the protruding pattern; a field insulating film on a sidewall of the protruding pattern; a gate electrode on an upper surface of the field insulating film and extending in a third direction; a source/drain pattern on at least one side of the gate electrode and connected to the first channel pattern; and a field capping film between the upper surface of the field insulating film and a bottom surface of the gate electrode, the field capping film including silicon (Si) and nitrogen (N).

According to an aspect of the disclosure, a semiconductor device includes: a field insulating film; a field capping film on an upper surface of the field insulating film, the field capping film including silicon oxynitride; a channel isolation pattern extending in a first direction on the field insulating film, wherein the channel isolation pattern includes silicon nitride and is in contact with the field capping film; a first channel pattern on the channel isolation pattern and overlapping with the channel isolation pattern in a second direction; a source/drain pattern on the channel isolation pattern and connected to the first channel pattern; and a gate structure on the field capping film, wherein the gate structure extends in a third direction and includes a gate electrode and a gate spacer, and wherein the gate structure is on a side of the source/drain pattern.

According to an aspect of the disclosure, a semiconductor device includes: a protruding pattern extending in a first direction; a first channel pattern on the protruding pattern and overlapping with the protruding pattern in a second direction; a channel isolation pattern between the protruding pattern and the first channel pattern, the channel isolation pattern including silicon nitride and extending in the first direction along an upper surface of the protruding pattern; a field insulating film on a sidewall of the protruding pattern, the field insulating film including silicon oxide; a source/drain pattern on the channel isolation pattern and connected to the first channel pattern; a gate electrode on an upper surface of the field insulating film, wherein the gate electrode extends in a third direction and is on a side of the source/drain pattern; a gate spacer on a sidewall of the gate electrode; and a field capping film between the field insulating film and the gate electrode, wherein the field capping film is between the gate spacer and the field insulating film, is in contact with the channel isolation pattern, and includes silicon oxynitride.

According to an aspect of the disclosure, a method of manufacturing a semiconductor device includes: forming a first fin-shaped pattern and a second fin-shaped pattern on a first substrate, wherein the first and the second fin-shaped patterns extend in a first direction, and are spaced apart in a second direction; forming fin hard mask on the first and the second fin-shaped patterns; forming a first pre-field insulating film on the first substrate 100, wherein the first pre-field insulating film is on at least a portion of a sidewall of the first fin-shaped pattern and a portion of a sidewall of the second fin-shaped pattern; forming fin protection spacers on the first pre-field insulating film, the fin protection spacers extending along a portion of the sidewall of the first fin-shaped pattern and at least a portion of the sidewall of the second fin-shaped pattern; forming a second pre-field insulating film on the first substrate by removing part of the first pre-field insulating film, wherein the second pre-field insulating film is on the sidewalls the first fin-shaped pattern and the sidewalls of the second fin-shaped pattern; forming first and second nitrogen implantation regions in the first and the second fin-shaped patterns, respectively, through a plasma process; forming a nitrogen-implanted field capping film on the first substrate; after the forming the first and the second nitrogen implantation regions, removing the fin protection spacers; forming a capping field insulating film on the nitrogen-implanted field capping film and removing the fin hard mask; forming a first channel isolation pattern and a second channel isolation pattern by subjecting the first and the second nitrogen implantation regions to a heat treatment; during the formation of the first and the second channel isolation patterns, transforming the nitrogen-implanted field capping film into a field capping film including silicon oxynitride; removing the capping field insulating film; forming a dummy gate electrode on the field capping film; forming gate spacers on sidewalls of the dummy gate electrode; forming source/drain recesses in the first pre-channel film using the gate spacers and the dummy gate electrode as a mask; forming first source/drain patterns on the first channel isolation pattern; forming a source/drain etching stop film and a first interlayer insulating film on each of the first source/drain patterns; exposing an upper surface of the dummy gate electrode by removing a portion of the first interlayer insulating film, the source/drain etching stop film, and the dummy gate capping film; during the exposure of the upper surface of the dummy gate electrode, removing portions of the gate spacers; exposing the first channel patterns by removing the dummy gate insulating film and the dummy gate electrode, thereby forming gate trenches; forming a gate insulating film and a gate electrode in each of the gate trenches; and forming a gate capping pattern on the gate electrodes.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent from the following description taken in conjunction with the accompanying drawings, in which:

FIG. 1 is an example plan view illustrating a semiconductor device according to one or more embodiments;

FIGS. 2, 3, 4 and 5 are cross-sectional views taken along lines A-A, B-B, C-C, and D-D, respectively, of FIG. 1;

FIG. 6 is a schematic graph showing the nitrogen concentration along the “SCAN LINE” of FIG. 5;

FIG. 7 is a diagram illustrating a semiconductor device according to one or more embodiments;

FIGS. 8 and 9 are diagrams illustrating semiconductor devices according to one or more embodiments;

FIG. 10 is a diagram illustrating a semiconductor device according to one or more embodiments;

FIGS. 11 and 12 are diagrams illustrating a semiconductor device according to one or more embodiments;

FIGS. 13 and 14 are diagrams illustrating a semiconductor device according to one or more embodiments;

FIGS. 15 and 16 are diagrams illustrating a semiconductor device according to one or more embodiments;

FIGS. 17 and 18 are diagrams illustrating a semiconductor device according to one or more embodiments;

FIGS. 19 through 32 are diagrams illustrating intermediate operations of a method for fabricating a semiconductor device according to one or more embodiments; and

FIGS. 33 and 34 are diagrams illustrating intermediate operations of a method for fabricating a semiconductor device according to one or more embodiments.

### DETAILED DESCRIPTION

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

Semiconductor devices according to one or more embodiments may include tunneling FETs, three-dimensional (3D) transistors, or two-dimensional (2D) material-based transistors (or FETs) and their heterostructures. Further, the semiconductor devices according to one or more embodiments may include bipolar junction transistors or lateral double-diffused metal-oxide-semiconductor transistors (LDMOSs).

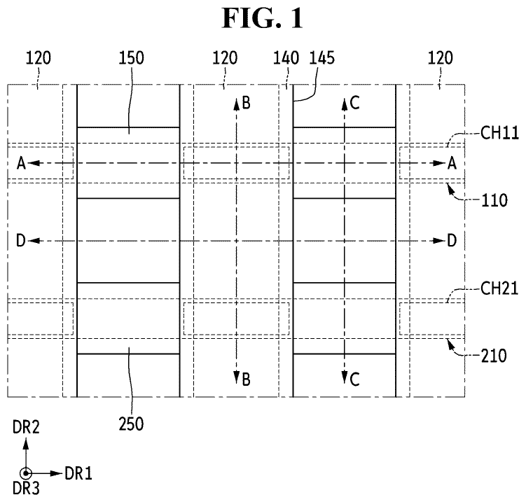

A semiconductor device according to one or more embodiments will hereinafter be described with reference to FIGS. 1 through 6.

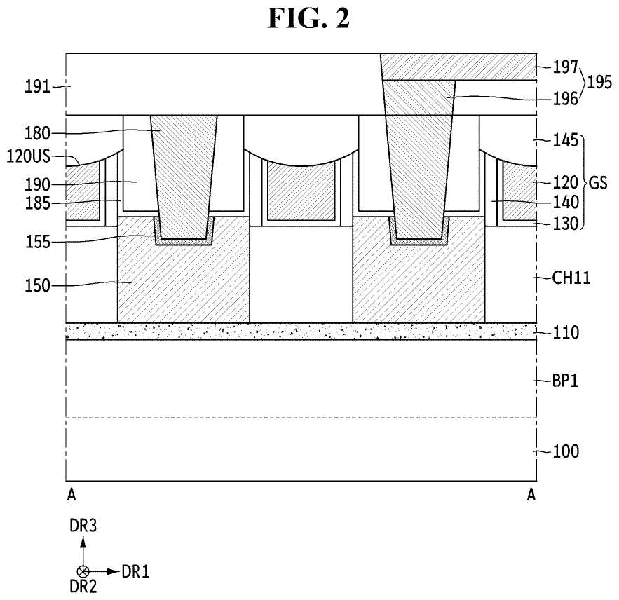

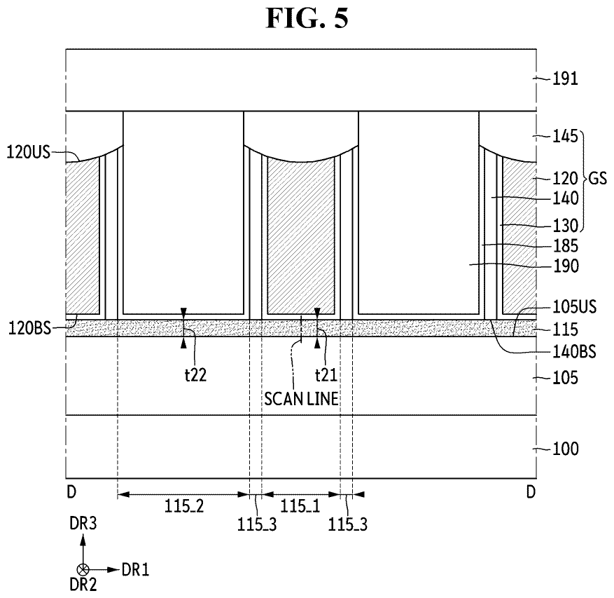

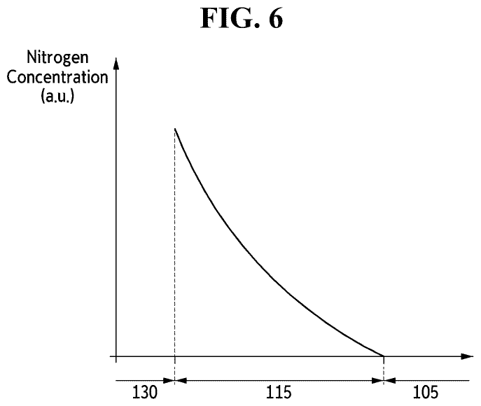

FIG. 1 is an example plan view illustrating a semiconductor device according to one or more embodiments. FIGS. 2 through 5 are cross-sectional views taken along lines A-A, B-B, C-C, and D-D, respectively, of FIG. 1. FIG. 6 is a schematic graph showing the nitrogen concentration along the “SCAN LINE” of FIG. 5.

For convenience of explanation, FIG. 1 omits the illustration of some elements such as gate insulating films 130, a source/drain etching stop film 185, first and second interlayer insulating films 190 and 191, and a front-side wiring structure 195.

Referring to FIGS. 1 through 6, the semiconductor device according to one or more embodiments may include first protruding patterns BP1, second protruding patterns BP2, a field capping film 115, first channel isolation patterns 110, second channel isolation patterns 210, first channel patterns CH11, second channel patterns CH21, gate electrodes 120, first source/drain patterns 150, and second source/drain patterns 250.

The first substrate 100 may include bulk silicon (Si) or Si-on-insulator (SOI). Alternatively, the first substrate 100 may include Si or other materials, such as silicon-germanium (SiGe), SiGe-on-insulator (SGOI), indium antimonide, a lead telluride compound, indium arsenide, indium phosphide, gallium arsenide, or gallium antimonide, but the disclosure is not limited thereto.

The first protruding patterns BP1 may protrude from the first substrate 100 in a third direction DR3. The first protruding patterns BP1 may extend longitudinally in a first direction DR1. The first protruding patterns BP1 may include long sides extending in the first direction DR1 and short sides extending in a second direction DR2.

The second protruding patterns BP2 may protrude from the first substrate 100 in the third direction DR3. The second protruding patterns BP2 may extend longitudinally in the first direction DR1. The second protruding patterns BP2 may be spaced apart from the first protruding patterns BP1 in the second direction DR2.

In the semiconductor device according to one or more embodiments, the upper surfaces of the first protruding patterns BP1 and the second protruding patterns BP2 may be planar in a cross-sectional view.

For example, the first and second directions DR1 and DR2 may be orthogonal to the third direction DR3. The first direction DR1 may also be orthogonal to the second direction DR2.

The first protruding patterns BP1 and the second protruding patterns BP2 may be formed by etching portions of the first substrate 100 or may include epitaxial layers grown from the first substrate 100. The first protruding patterns BP1 and the second protruding patterns BP2 may each include an elemental semiconductor material such as Si or Ge. Additionally, the first protruding patterns BP1 and the second protruding patterns BP2 may each include a compound semiconductor, for example, a Group IV-IV compound semiconductor or a Group III-V compound semiconductor.

The Group IV-IV compound semiconductor may include a binary or ternary compound containing at least two of carbon (C), Si, Ge, and tin (Sn), or a compound obtained by doping the binary or ternary compound with a Group IV element.

The Group III-V compound semiconductor may include a binary, ternary, or quaternary compound obtained by combining at least one Group III element, such as aluminum (Al), gallium (Ga), and indium (In), with at least one Group V element, such as phosphorus (P), arsenic (As), and antimony (Sb).

A field insulating film 105 may be disposed on the first substrate 100. The field insulating film 105 may be disposed on the sidewalls of the first protruding patterns BP1. The field insulating film 105 may also be disposed on the sidewalls of the second protruding patterns BP2. The field insulating film 105 is not disposed on the upper surfaces of the first protruding patterns BP1 and the upper surfaces of the second protruding patterns BP2.

The field insulating film 105 may cover the entire sidewalls of the first protruding patterns BP1 and the entire sidewalls of the second protruding patterns BP2. Alternatively, the field insulating film 105 may cover only portions of the sidewalls of the first protruding patterns BP1 and only portions of the sidewalls of the second protruding patterns BP2. In this case, the first protruding patterns BP1 and the second protruding patterns BP2 may partially protrude in the third direction DR3 beyond an upper surface 105US of the field insulating film 105.

The upper surface 105US of the field insulating film 105 may have a concave shape, but the disclosure is not limited thereto. For example, the field insulating film 105 may include silicon oxide.

The field insulating film 105 is illustrated as a single layer, but the disclosure is not limited thereto. When the field insulating film 105 is a multilayer film, the field insulating film 105 may include a field insulating liner and a field insulating filling film. The field insulating liner may extend along the sidewalls of the first protruding patterns BP1, the sidewalls of the second protruding patterns BP2, and the upper surface of the first substrate 100. The field insulating liner may define field insulating recesses that resemble a “U” shape in a cross-sectional view. The field insulating filling film may be disposed on the field insulating liner. The field insulating filling liner may fill the field insulating recesses. The field insulating liner may be disposed between the field insulating filling film, the first protruding patterns BP1, and the second protruding patterns BP2. The field insulating liner may include one of silicon nitride or silicon oxynitride. The field insulating filling film may include silicon oxide.

A field capping film 115 may be disposed on the field insulating film 105. The field capping film 115 may extend along the upper surface 105US of the field insulating film 105. The field capping film 115 may contact the upper surface 105US of the field insulating film 105. The field capping film 115 is not disposed on the upper surfaces of the first protruding patterns BP1 and the upper surfaces of the second protruding patterns BP2.

The field capping film 115 may include Si and nitrogen (N). For example, the field capping film 115 may include silicon oxynitride. In FIG. 6, the N concentration (concentration per cm³) in the field capping film 115 may decrease as the distance from a bottom surface 120BS of the gate electrode 120 increases. If a thickness t21 of the field capping film 115 is small, the N concentration in the silicon oxynitride of the field capping film 115 may appear uniform. For example, the N concentration in the field capping film 115 may be measured along a scan line “SCAN LINE” passing through the width center of the gate electrode 120.

The upper surface 105US of the field insulating film, which is the boundary between the field insulating film 105 and the field capping film 115, may be distinguished using the nitrogen (N) concentration. If the field insulating film 105 is a multilayer film including the field insulating liner and the field insulating filling film, the upper surface 105US of the field insulating film at the boundary with the field capping film 115 may be distinguished using changes in the nitrogen concentration between the field insulating filling film and the field capping film 115.

The field capping film 115 will be described later in further detail.

The first channel isolation patterns 110 may be disposed on the first protruding patterns BP1 and the field insulating film 105. The first channel isolation patterns 110 overlaps with the first protruding patterns BP1 in the third direction DR3. The first channel isolation patterns 110 may contact the first protruding patterns BP1.

The first channel isolation patterns 110 may be disposed on the upper surfaces of the first protruding patterns BP1. The first channel isolation patterns 110 may extend in the first direction DR1 along the upper surfaces of the first protruding patterns BP1.

The first channel isolation patterns 110 may each include an upper surface 110US and a bottom surface 110BS opposite to each other in the third direction DR3. The upper surfaces 110US of the first channel isolation patterns 110 may face the first channel patterns CH11. The bottom surfaces 110BS of the first channel isolation patterns 110 may contact the first protruding patterns BP1. The first channel isolation patterns 110 are disposed between the first protruding patterns BP1 and the first channel patterns CH11.

Each of the first channel isolation patterns 110 may include sidewalls connecting its upper surface 110US and bottom surface 110BS. For example, the first channel isolation patterns 110 may contact the field capping film 115. The field capping film 115 may contact the sidewalls of each of the first channel isolation patterns 110.

The second channel isolation patterns 210 may be disposed on the second protruding patterns BP2 and the field insulating film 105. The second channel isolation patterns 210 may overlap with the second protruding patterns BP2 in the third direction DR3. The second channel isolation patterns 210 may contact the second protruding patterns BP2. For example, the second channel isolation patterns 210 may contact the field capping film 115.

The second channel isolation patterns 210 may be spatially separated from the first channel isolation patterns 110. The second channel isolation patterns 210 may be spaced apart from the first channel isolation patterns 110 in the second direction DR2.

The second channel isolation patterns 210 may each include an upper surface 210US and a bottom surface 210BS opposite to each other in the third direction DR3. The upper surfaces 210US of the second channel isolation patterns 210 may face the second channel patterns CH21. The bottom surfaces 210BS of the second channel isolation patterns 210 may contact the second protruding patterns BP2. The second channel isolation patterns 210 are disposed between the second protruding patterns BP2 and the second channel patterns CH21.

The first channel isolation patterns 110 and the second channel isolation patterns 210 may include Si and N. For example, the first channel isolation patterns 110 and the second channel isolation patterns 210 may include silicon nitride.

The first channel patterns CH11 may be disposed on the first channel isolation patterns 110. The first channel patterns CH11 overlap with the first channel isolation patterns 110 in the third direction DR3. For example, the first channel patterns CH11 may be spaced apart from each other in the first direction DR1.

The first channel patterns CH11 may be disposed on the first protruding patterns BP1. The first channel patterns CH11 overlap with the first protruding patterns BP1 in the third direction DR3. The first channel patterns CH11 may be spaced apart from the first protruding patterns BP1 in the third direction DR3 with the first channel isolation patterns 110 interposed therebetween.

The second channel patterns CH21 may be disposed on the second channel isolation patterns 210. The second channel patterns CH21 overlap with the second channel isolation patterns 210 in the third direction DR3. For example, the second channel patterns CH21 may be spaced apart from each other in the first direction DR1.

The second channel patterns CH21 may be disposed on the second protruding patterns BP2. The second channel patterns CH21 overlap with the second protruding patterns BP2 in the third direction DR3. The second channel patterns CH21 may be spaced apart from the second protruding patterns BP2 in the third direction DR3 with the second channel isolation patterns 210 interposed therebetween.

In the semiconductor device according to one or more embodiments, the first channel patterns CH11 may contact the first channel isolation patterns 110, and the second channel patterns CH21 may contact the second channel isolation patterns 210. The first channel patterns CH11 may contact the upper surfaces 110US of the first channel isolation patterns 110. The second channel patterns CH21 may contact the upper surfaces 210US of the second channel isolation patterns 210.

The first channel patterns CH11 and the second channel patterns CH21 may each include an elemental semiconductor material such as Si or Ge, a Group IV-IV compound semiconductor, or a Group III-V compound semiconductor. The first channel patterns CH11 may include the same material as or a different material from the first protruding patterns BP1. Similarly, the second channel patterns CH21 may include the same material as or a different material from the second protruding patterns BP2.

In the semiconductor device according to one or more embodiments, the first protruding patterns BP1 and the second protruding patterns BP2 may be Si protruding patterns including Si. The first channel patterns CH11 and the second channel patterns CH21 may be Si channel patterns including Si.

For example, the first channel patterns CH11 and the second channel patterns CH21 may be disposed in a P-type metal-oxide semiconductor (PMOS) region. Alternatively, the first channel patterns CH11 and the second channel patterns CH21 may be disposed in an N-type metal-oxide semiconductor (NMOS) region. In another example, either the first channel patterns CH11 or the second channel patterns CH21 may be disposed in a PMOS region, and the other channel patterns may be disposed in an NMOS region.

A plurality of gate structures GS may be disposed on the first substrate 100. The gate structures GS may each extend in the second direction DR2. The gate structures GS may be spaced apart from each other in the first direction DR1. The gate structures GS may be adjacent to each other in the first direction DR1.

For example, the gate structures GS may be disposed on both sides of the first source/drain patterns 150 in the first direction DR1. The gate structures GS may also be disposed on both sides of the second source/drain patterns 250 in the first direction DR1.

The gate structures GS may be disposed on the first protruding patterns BP1 and the second protruding patterns BP2. The gate structures GS may be disposed on the first channel isolation patterns 110 and the second channel isolation patterns 210. The gate structures GS may be disposed on the first channel patterns CH11 and the second channel patterns CH21. The gate structures GS may intersect the first protruding patterns BP1 and the second protruding patterns BP2. The gate structures GS may intersect the first channel isolation patterns 110 and the second channel isolation patterns 210.

The gate structures GS may be disposed on the upper surface 105US of the field insulating film 105. For example, the gate structures GS may be disposed on the field capping film 115. The gate structures GS may include the gate electrodes 120, the gate insulating films 130, gate spacers 140, and gate capping patterns 145.

The gate structures GS are illustrated as being disposed across pairs of adjacent first and second channel patterns CH11 and CH21, but the disclosure is not limited thereto. For example, some of the gate structures GS may each be divided into two portions disposed on a pair of adjacent first and second channel isolation patterns 110 and 210, respectively. That is, first gate structures on the first channel isolation patterns 110 and the first channel patterns CH11 may be separated in the second direction DR2 from second gate structures on the second channel isolation patterns 210 and the second channel patterns CH21. In this case, first gate electrodes and first gate insulating films included in the first gate structures may be separated from on the first channel isolation patterns 110 and the first channel patterns CH11, may be separated from second gate electrodes and second gate insulating films included in the second gate structures.

The gate electrodes 120 may be disposed on the first protruding patterns BP1 and the second protruding patterns BP2. The gate electrodes 120 may be disposed on the first channel isolation patterns 110 and the second channel isolation patterns 210. The gate electrodes 120 may be disposed on the first channel patterns CH11 and the second channel patterns CH21.

The gate electrodes 120 may be disposed on the upper surface 105US of the field insulating film 105. For example, the gate electrodes 120 may be disposed on the field capping film 115. The gate electrodes 120 may each include an upper surface 120US and a bottom surface 120BS opposite to each other in the third direction DR3. The bottom surfaces 120BS of the gate electrodes 120 may face the field capping film 115. The upper surfaces 120US of the gate electrodes 120 are illustrated as having a concave shape but the disclosure is not limited thereto. Sidewalls of the gate electrodes 120 extending in the second direction DR2 may connect the bottom surfaces 120BS and the upper surfaces 120US of the gate electrodes 120.

The gate electrodes 120 may include, for example, at least one of a metal, a conductive metal nitride, a conductive metal carbonitride, a conductive metal carbide, a metal silicide, a doped semiconductor material, a conductive metal oxynitride, or a conductive metal oxide. For example, the gate electrodes 120 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel-platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. Here, the conductive metal oxide and conductive metal oxynitride may include oxidized forms of the aforementioned materials but the disclosure is not limited thereto.

The gate electrodes 120 may be disposed on both sides of the first source/drain patterns 150, which will be described later. For example, the gate electrodes 120 disposed on both sides of the first source/drain patterns 150 may all serve as normal gate electrodes used as transistor gates. In another example, the gate electrodes 120 disposed on first sides of the first source/drain patterns 150 may serve as transistor gates, and the gate electrodes 120 disposed on second sides of the first source/drain patterns 150 may be a dummy gate electrode.

The gate insulating films 130 may be disposed on the field capping film 115. The gate insulating films 130 may extend along the upper surface 105US of the field insulating film 105. The gate insulating films 130 may also extend along the sidewalls and upper surfaces of the first channel patterns CH11 and along the sidewalls and bottom surfaces of the second channel patterns CH21.

The gate electrodes 120 may be disposed on the gate insulating films 130. The gate insulating films 130 may be positioned between the first channel patterns CH11 and the gate electrodes 120, between the second channel patterns CH21 and the gate electrodes 120, and between the field capping film 115 and the gate electrodes 120.

The gate insulating films 130 may include silicon oxide, silicon-germanium oxide, germanium oxide, silicon oxynitride, silicon nitride, or a high-k material with a dielectric constant greater than that of silicon oxide. The high-k material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate insulating films 130 are illustrated as single layers for convenience, but the disclosure is not limited thereto. The gate insulating films 130 may each include multiple layers. The gate insulating films 130 may include high-k dielectric films, and interfacial layers disposed between the gate electrodes 120 and the first channel patterns CH1 and between the gate electrodes 120 and the second channel patterns CH21.

The semiconductor device according to one or more embodiments of the present disclosure may include a negative capacitance (NC) FET utilizing a negative capacitor. For example, the gate insulating films 130 may each include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one of hafnium oxide, hafnium zirconium oxide, barium strontium titanium oxide, barium titanium oxide, or lead zirconium titanium oxide. Here, the hafnium zirconium oxide may be, for example, a material obtained by doping hafnium oxide with zirconium (Zr). Alternatively, the hafnium zirconium oxide may be the compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), or Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one of Gd, Si, Zr, Al, or Y.

If the dopant is Al, the ferroelectric material film may contain 3 to 8 atomic % (at %) of Al. Here, the proportion of the dopant may be the ratio of Al to the sum of Hf and Al.

If the dopant is Si, the ferroelectric material film may contain 2 to 10 at % of Si. If the dopant is Y, the ferroelectric material film may contain 2 to 10 at % of Y. If the dopant is Gd, the ferroelectric material film may contain 1 to 7 at % of Gd. If the dopant is Zr, the ferroelectric material film may contain 50 to 80 at % of Zr.

The paraelectric material film may have paraelectric properties. For example, the paraelectric material film may include at least one of silicon oxide or a high-k metal oxide. The high-k metal oxide may include at least one of hafnium oxide, zirconium oxide, or aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the present disclosure is not limited thereto. Since the critical thickness for exhibiting ferroelectric properties may vary from one ferroelectric material to another, the thickness of the ferroelectric material film may vary depending on its material.

For example, the gate insulating films 130 may each include one ferroelectric material film. Alternatively, the gate insulating films 130 may each include a plurality of ferroelectric material films that are spaced apart from one another. The gate insulating films 130 may each have a layered film structure in which a plurality of ferroelectric material films and a plurality of paraelectric material films are alternately stacked.

The gate spacers 140 may be disposed on the sidewalls of the gate electrodes 120. The gate spacers 140 may also be disposed on the field insulating film 105. For example, the gate spacers 140 may be disposed on the field capping film 115.

The gate spacers 140 may each include a bottom surface 140BS facing the field insulating film 105. For example, the gate spacers 140 may contact the field capping film 115.

The gate spacers 140 may include, for example, silicon nitride, silicon oxynitride, silicon oxide, silicon oxynitride carbide, silicon boron nitride, silicon oxyboron nitride, silicon oxycarbide, or a combination thereof. The gate spacers 140 are illustrated as single layers, but the disclosure is not limited thereto.

The gate capping patterns 145 may be disposed on the gate electrodes 120 and the gate spacers 140. The gate capping patterns 145 may be disposed on the upper surfaces 120US of the gate electrodes 120. The upper surfaces of the gate capping patterns 145 may lie on the same plane as the upper surface of the first interlayer insulating film 190, but the present disclosure is not limited thereto. In one or more embodiments, the gate capping patterns 145 may be disposed between the gate spacers 140.

The gate capping patterns 145 may include, for example, silicon nitride, silicon oxynitride, silicon carbonitride, silicon oxycarbonitride, or a combination thereof. The gate capping patterns 145 may include a material with an etching selectivity with respect to the first interlayer insulating film 190.

In one or more embodiments, the gate capping patterns 145 may not be disposed on the gate electrodes 120. That is, the gate structures GS may not include the gate capping patterns 145.

The first source/drain patterns 150 may be disposed on the first channel isolation patterns 110. The first source/drain patterns 150 may overlap with the first channel isolation patterns 110 in the third direction DR3. The first source/drain patterns 150 may connect to the first channel patterns CH11. The first channel isolation patterns 110 may be disposed between the first source/drain patterns 150 and the first protruding patterns BP1.

The first source/drain patterns 150 may be disposed on at least one side of the gate electrodes 120. The first source/drain patterns 150 may be positioned between adjacent first gate electrodes 120 in the first direction DR1. For example, the first source/drain patterns 150 may be disposed on both sides of the gate electrodes 120. In one or more embodiments, the first source/drain patterns 150 may be disposed on one side, but not on the other side, of the gate electrodes 120.

The second source/drain patterns 250 may be disposed on the second channel isolation patterns 210. The second source/drain patterns 250 may overlap with the second channel isolation patterns 210 in the third direction DR3. The second source/drain patterns 250 may be connected to the second channel patterns CH21. The second channel isolation patterns 210 may be disposed between the second source/drain patterns 250 and the second protruding patterns BP2.

The first source/drain patterns 150 and the second source/drain patterns 250 may be included as sources/drains of transistors using the first channel patterns CH11 and the second channel patterns CH21 as channel regions.

The first source/drain patterns 150 and the second source/drain patterns 250 may include epitaxial patterns. The first source/drain patterns 150 and the second source/drain patterns 250 may include a semiconductor material. The first source/drain patterns 150 and the second source/drain patterns 250 are illustrated as having a pentagonal cross-sectional shape, but the disclosure is not limited thereto. Alternatively, the first source/drain patterns 150 and the second source/drain patterns 250 may have a hexagonal or rectangular cross-sectional shape.

The first source/drain patterns 150 and the second source/drain patterns 250 may each include an elemental semiconductor material such as Si or Ge. Alternatively, the first source/drain patterns 150 and the second source/drain patterns 250 may each include a binary or ternary compound containing at least two of C, Si, Ge, and Sn, or a compound obtained by doping the binary or ternary compound with a Group IV element. For example, if the first source/drain patterns 150 or the second source/drain patterns 250 are included in the source/drain regions of p-type transistors, they may each include an SiGe film. In another example, if the first source/drain patterns 150 or the second source/drain patterns 250 are included in the source/drain regions of n-type transistors, they may each include an Si film. However, the present disclosure is not limited to these examples.

The first source/drain patterns 150 and the second source/drain patterns 250 may each include impurities doped into a semiconductor material. For example, if the first source/drain patterns 150 and the second source/drain patterns 250 are included in the source/drain regions of p-type transistors, they may include p-type impurities. The P-type impurities may include, for example, at least one of boron (B) or Ga. In another example, if the first source/drain patterns 150 and the second source/drain patterns 250 are included in the source/drain regions of n-type transistors, they may include n-type impurities. The n-type impurities may include, for example, at least one of P, As, Sb, or bismuth (Bi).

The first source/drain patterns 150 and the second source/drain patterns 250 are illustrated as single layers, but the disclosure is not limited thereto.

The source/drain etching stop film 185 may be disposed on the sidewalls of the gate spacers 140 and on the upper surfaces of the source/drain patterns 150. The source/drain etching stop film 185 may also be disposed on the field insulating film 105. For example, the source/drain etching stop film 185 may extend along the upper surface 105US of the field insulating film 105.

The source/drain etching stop film 185 may include a material with etching selectivity with respect to the first interlayer insulating film 190, which will be described later. For example, the source/drain etching stop film 185 may include silicon nitride, silicon oxynitride, silicon oxycarbonitride, silicon boron nitride, silicon oxyboron nitride, silicon oxycarbide, or a combination thereof.

The first interlayer insulating film 190 may be disposed on the source/drain etching stop film 185. The first interlayer insulating film 190 may be disposed on the first source/drain patterns 150 and the second source/drain patterns 250. The first interlayer insulating film 190 may not cover the upper surfaces of the first gate capping patterns 145.

The first interlayer insulating film 190 may include, for example, at least one of silicon oxide, silicon nitride, silicon oxynitride, or low-k material. The low-k material may include, for instance, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetratluoroethylene (PTFE), tonen silazen (TOSZ), fluoride silicate glass (FSG), polypropylene oxide-based polyimide nanofoams, carbon doped silicon oxide (CDO), organo silicate glass (OSG), SiLK, amorphous fluorinated carbon, silica aerogels, silica xerogels, mesoporous silica, or a combination thereof, but the disclosure is not limited thereto.

The field capping film 115 may be disposed between the gate electrodes 120 and the field insulating film 105 and between the gate spacers 140 and the field insulating film 105. The field capping film 115 may also be disposed between the bottom surfaces 120BS of the gate electrodes 120 and the upper surface 105US of the field insulating film 105, as well as between the bottom surfaces 140BS of the gate spacers 140 and the upper surface 105US of the field insulating film 105.

In the semiconductor device according to one or more embodiments, the field capping film 115 may be disposed between the field insulating film 105 and the first interlayer insulating film 190. For example, the field capping film 115 may be disposed between the source/drain etching stop film 185 and the field insulating film 105.

The field capping film 115 may include first regions 115_1, second regions 115_2, and third regions 115_3.

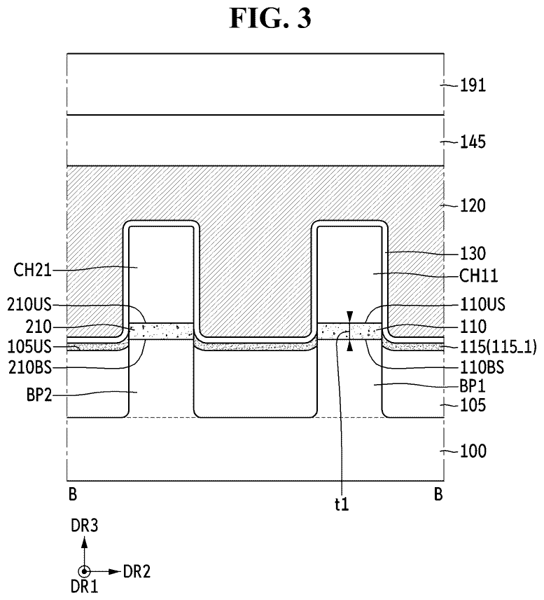

The first regions 115_1 of the field capping film 115 may be disposed between the gate electrodes 120 and the field insulating film 105. The first regions 115_1 of the field capping film 115 may be disposed between the bottom surfaces 120BS of the gate electrodes 120 and the upper surface 105US of the field insulating film 105. In FIG. 3, the first regions 115_1 of the field capping film 115 may be disposed between pairs of adjacent first and second channel patterns CH11 and CH21 in the second direction DR2. The first regions 115_1 of the field capping film 115 may also be disposed between pairs of adjacent first and second channel isolation patterns 110 and 210 in the second direction DR2.

The second regions 115_2 of the field capping film 115 may be disposed between the field insulating film 105 and the first interlayer insulating film 190. The second regions 115_2 of the field capping film may be disposed between adjacent gate structures GS in the first direction DR1. The first regions 115_1 and the second regions 115_2 of the field capping film 115 may be alternately arranged in the first direction DR1.

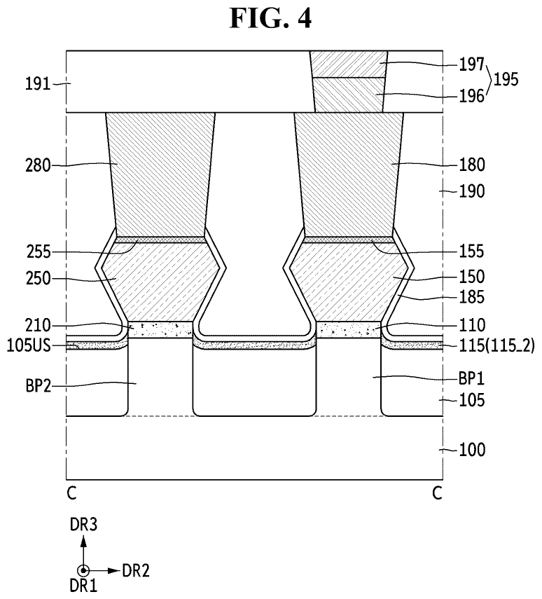

In FIG. 4, the second regions 115_2 of the field capping film 115 may be disposed on both sides of the first source/drain patterns 150. The second regions 115_2 of the field capping film 115 may also be disposed on both sides of the second source/drain patterns 250. The second regions 115_2 of the field capping film 115 may be disposed between pairs of adjacent first and second source/drain patterns 150 and 250 in the second direction DR2. Either the first source/drain patterns 150 or the second source/drain patterns 250 may be disposed between adjacent second regions 115_2 of the field capping film 115 in the second direction DR2. The second regions 115_2 of the field capping film 115 may also be disposed between pairs of adjacent first and second channel isolation patterns 110 and 210 in the second direction DR2.

The third regions 115_3 of the field capping film 115 may be disposed between the gate spacers 140 and the field insulating film 105. The third regions 115_3 of the field capping film 115 may be disposed between the bottom surfaces 140BS of the gate spacers 140 and the upper surface 105US of the field insulating film 105. The third regions 115_3 of the field capping film 115 may be disposed between the first regions 115_1 and the second regions 115_2 of the field capping film 115.

For example, a thickness t21 of the first regions 115_1 of the field capping film 115 in the third direction DR3 may be the same as a thickness t22 of the second regions 115_2 of the field capping film 115 in the third direction DR3. The thickness t21 of the first regions 115_1 of the field capping film 115 may also be the same as the thickness of the third regions 115_3 of the field capping film 115. In one or more embodiments, the thickness t21 of the first regions 115_1 of the field capping film 115 may be smaller than the thickness of the third regions 115_3 of the field capping film 115.

A thickness t1 of, for example, the first channel isolation patterns 110 in the third direction DR3 may be greater than the thickness t21 of the first regions 115_1 of the field capping film 115, but the present disclosure is not limited thereto. In one or more embodiments, for example, the thickness t1 of the first channel isolation patterns 110 may be equal to the thickness t21 of the first regions 115_1 of the field capping film 115. Alternatively, the thickness t1 of the first channel isolation patterns 110 may be smaller than the thickness t21 of the first regions 115_1 of the field capping film 115.

The first channel isolation patterns 110 may prevent leakage current between adjacent first source/drain patterns 150 in the first direction DR1. Additionally, the first channel isolation patterns 110 may allow the bottom surfaces of the first source/drain patterns 150, arranged in the first direction DR1, to have a uniform height. Consequently, the performance and reliability of the semiconductor device according to one or more embodiments can be improved.

Moreover, the volume change during the conversion of silicon into silicon nitride is smaller than that during the conversion of silicon into silicon oxide. That is, the first channel isolation patterns 110 including silicon nitride may cause less damage to the first channel patterns CH11 compared to channel isolation patterns including silicon oxide.

Furthermore, silicon nitride has higher thermal conductivity than silicon oxide. The first channel isolation patterns 110 including silicon nitride may dissipate heat generated during the operation of the semiconductor device according to one or more embodiments more effectively than channel isolation patterns including silicon oxide. Therefore, the performance and reliability of the semiconductor device according to one or more embodiments can be further enhanced.

First front-side source/drain contacts 180 may be disposed on the first source/drain patterns 150. The first front-side source/drain contacts 180 may be connected to the first source/drain patterns 150. The first front-side source/drain contacts 180 may be connected to the first source/drain patterns 150 by passing through the first interlayer insulating film 190 and the source/drain etching stop film 185.

Second front-side source/drain contacts 280 may be disposed on the second source/drain patterns 250. The second front-side source/drain contacts 280 may be connected to the second source/drain patterns 250. The second front-side source/drain contacts 280 may be connected to the second source/drain patterns 250 by passing through the first interlayer insulating film 190 and the source/drain etching stop film 185.

The first front-side source/drain contacts 180 and the second front-side source/drain contacts 280 are illustrated as single layers, but the disclosure is not limited thereto. The first front-side source/drain contacts 180 and the second front-side source/drain contacts 280 may include, for example, metal, conductive metal nitride, conductive metal carbide, conductive metal oxide, conductive metal carbonitride, a 2D material, or a combination thereof. In the semiconductor device according to one or more embodiments, the 2D material may be a metallic material and/or a semiconductor material. The 2D material may include a 2D allotrope or 2D compound, and may include, for example, at least one of graphene, molybdenum disulfide (MoS₂), molybdenum diselenide (MoSe₂), tungsten diselenide (WSe₂), or tungsten disulfide (WS₂), but the disclosure is not limited thereto. The above-listed 2D materials are merely example and are not intended to limit the scope of the semiconductor device according to one or more embodiments.

First front-side contact silicide films 155 may be disposed between the first front-side source/drain contacts 180 and the first source/drain patterns 150. Second front-side contact silicide films 255 may be disposed between the second front-side source/drain contacts 280 and the second source/drain patterns 250. The first front-side contact silicide films 155 and the second front-side contact silicide films 255 may include metal silicide.

The second interlayer insulating film 191 may be disposed on the first interlayer insulating film 190. The second interlayer insulating film 191 may include, for example, at least one of silicon oxide, silicon nitride, silicon oxynitride, or a low-k material.

The front-side wiring structure 195 may be disposed within the second interlayer insulating film 191. The front-side wiring structure 195 may be connected to the first front-side source/drain contacts 180. The front-side wiring structure 195 may also be connected to the second front-side source/drain contacts 280. The front-side wiring structure 195 may include front-side wiring lines 197 and front-side wiring vias 196.

The front-side wiring lines 197 and the front-side wiring vias 196 are illustrated as distinct components, but the disclosure is not limited thereto. For example, the front-side wiring vias 196 may be formed first, and then the front-side wiring lines 197 may be formed. Alternatively, the front-side wiring vias 196 and the front-side wiring lines 197 may be formed simultaneously.

The front-side wiring lines 197 and the front-side wiring vias 196 are illustrated as single layers, but the disclosure is not limited thereto. The front-side wiring lines 197 and the front-side wiring vias 196 may each include, for example, at least one of a metal, conductive metal nitride, conductive metal carbide, conductive metal oxide, conductive metal carbonitride, or 2D material.

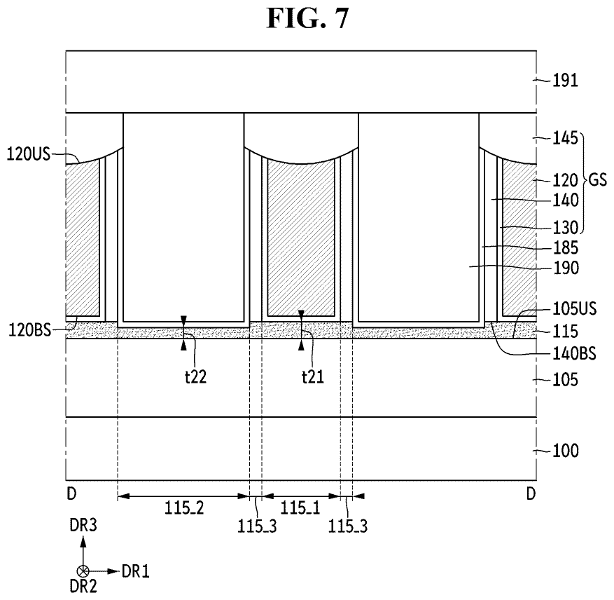

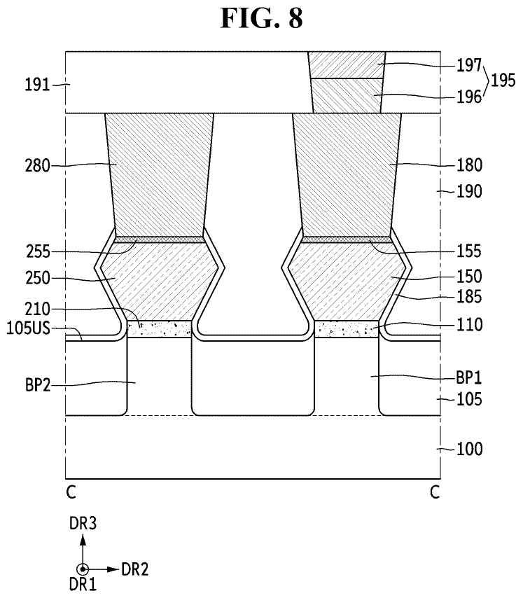

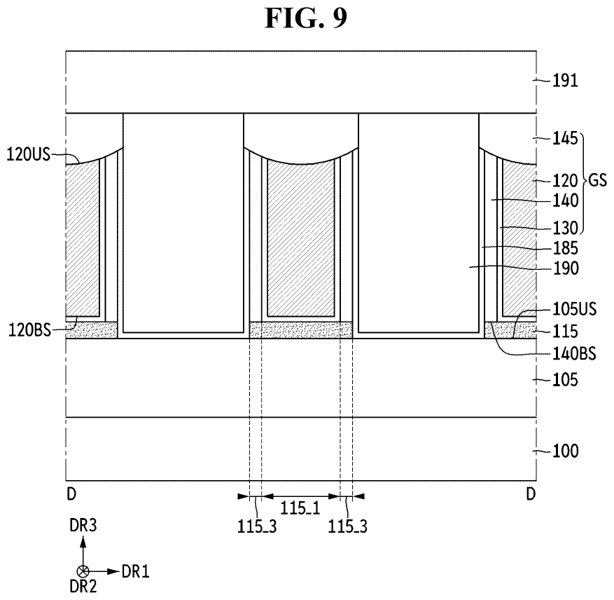

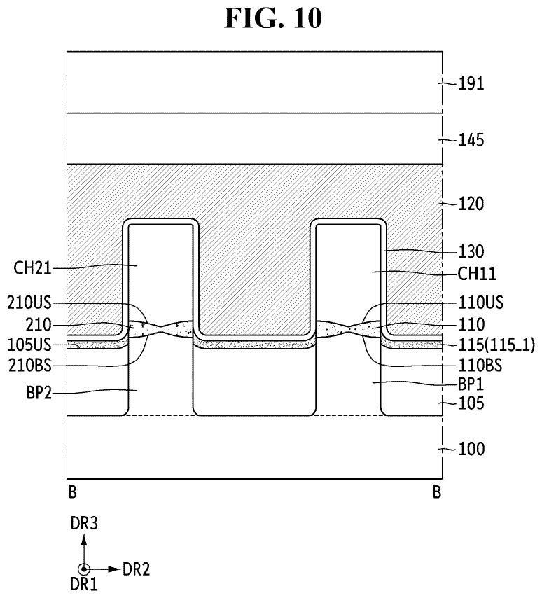

FIG. 7 is a diagram illustrating a semiconductor device according to one or more embodiments. FIGS. 8 and 9 illustrate are diagrams illustrating semiconductor devices according to one or more embodiments. FIG. 10 is a diagram illustrating a semiconductor device according to one or more embodiments. For convenience, the embodiments of FIGS. 7 through 10 will hereinafter be described, highlighting the differences from the embodiment of FIGS. 1 through 6.

Referring to FIG. 7, in the semiconductor device according to one or more embodiments, a thickness t21 of first regions 115_1 of a field capping film 115 may differ from a thickness t22 of second regions 115_2 of the field capping film 115.

For example, the thickness t21 of the first regions 115_1 of the field capping film 115 may be greater than the thickness t22 of the second regions 115_2 of the field capping film 115.

Referring to FIGS. 8 and 9, in the semiconductor device according to one or more embodiments, a field capping film 115 may not be disposed between adjacent gate structures GS in the first direction DR1.

The field capping film 115 may not be disposed between a field insulating film 105 and a source/drain etching stop film 185. The field capping film 115 may not be disposed between pairs of adjacent first and second source/drain patterns 150 and 250 in the second direction DR2.

The field capping film 115 may include first regions 115_1 disposed between gate electrodes 120 and the field insulating film 105, and third regions 115_3 disposed between gate spacers 140 and the field insulating film 105.

Referring to FIG. 10, in the semiconductor device according to one or more embodiments, the thickness of first channel isolation patterns 110 may decrease as the distance from the sidewalls of the first channel isolation patterns 110 increases.

In other words, the first channel isolation patterns 110 may each include a first sidewall and a second sidewall opposite to each other in the second direction DR2. The thickness of the first channel isolation patterns 110 may decrease and then increase as the distance from their first sidewalls increases.

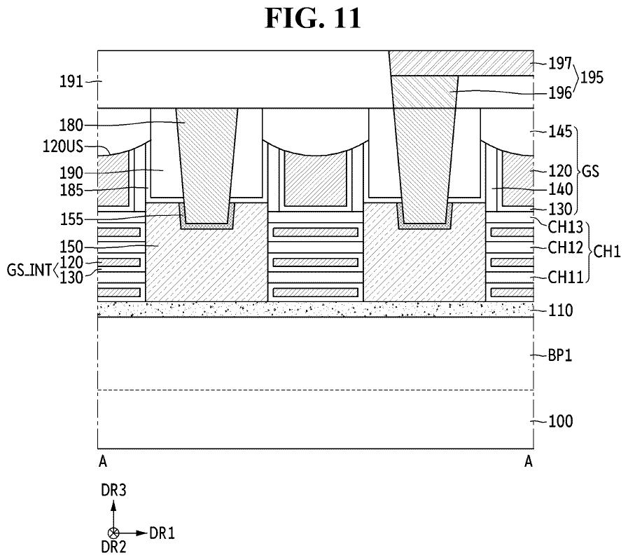

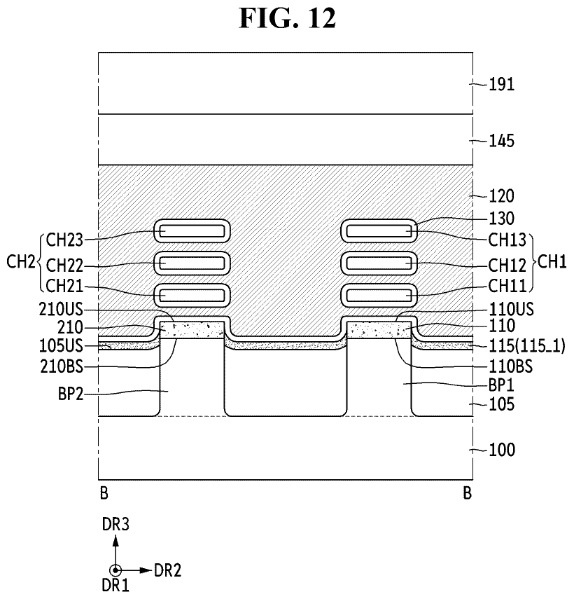

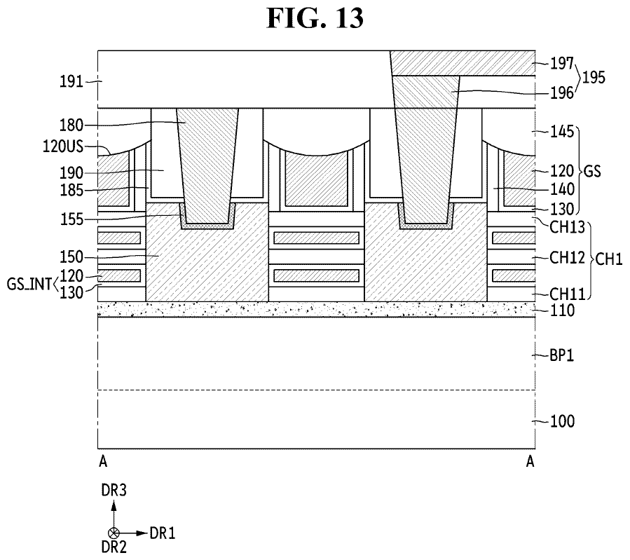

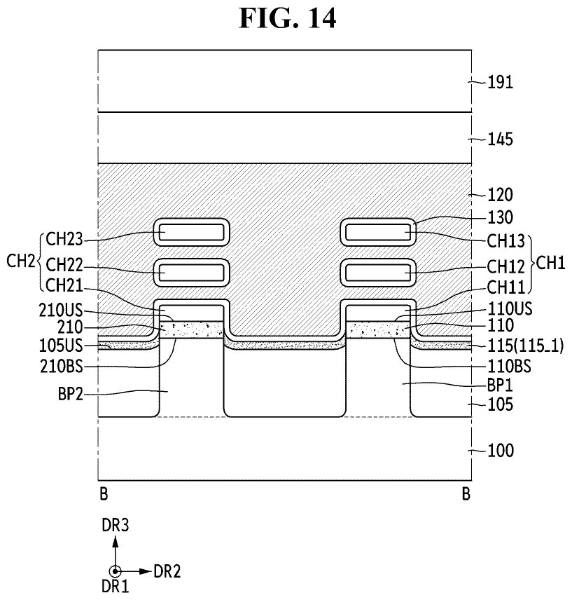

FIGS. 11 and 12 are diagrams illustrating a semiconductor device according to one or more embodiments. FIGS. 13 and 14 are diagrams illustrating a semiconductor device according to one or more embodiments. For convenience, the embodiments of FIGS. 11 through 14 will hereinafter be described, highlighting the differences from the embodiment of FIGS. 1 through 6.

Referring to FIGS. 11 through 14, the semiconductor devices according to one or more embodiments may each include first channel groups CH1 and second channel groups CH2.

The first channel groups CH1 may be disposed on a first channel isolation pattern 110. The first channel groups CH1 may each include a first channel pattern CH11, a third channel pattern CH12, and a fourth channel pattern CH13. The first channel pattern CH11, the third channel pattern CH12, and the fourth channel pattern CH13 may be spaced apart from each other in the third direction DR3.

The first, third, and fourth channel patterns CH11, CH12, and CH13 may overlap with the first channel isolation pattern 110 in the third direction DR3. The third and fourth channel patterns CH12 and CH13 may overlap with the first channel pattern CH11 in the third direction DR3. Among the channel patterns included in each of the first channel groups CH1, the first channel pattern CH11 may be the channel pattern closest to the first channel isolation pattern 110.

The second channel groups CH2 may be disposed on a second channel isolation pattern 210. The second channel groups CH2 may each include a second channel pattern CH21, a fifth channel pattern CH22, and a sixth channel pattern CH23. The second, fifth, and sixth channel patterns CH21, CH22, and CH23 may be spaced apart from each other in the third direction DR3.

The second, fifth, and sixth channel patterns CH21, CH22, and CH23 may overlap with the second channel isolation pattern 210 in the third direction DR3. The fifth and sixth channel patterns CH22 and CH23 may overlap with the second channel pattern CH21 in the third direction DR3. Among the channel patterns included in each of the second channel group CH2, the second channel pattern CH21 may be the channel pattern closest to the second channel isolation pattern 210.

The first channel groups CH1 and the second channel groups CH2 are illustrated as each including three channel patterns, but the disclosure is not limited thereto.

First source/drain patterns 150 may be connected to the first channel groups CH1. The first source/drain patterns 150 may be connected to the first channel patterns CH11, the third channel patterns CH12, and the fourth channel patterns CH13 of the first channel groups CH1.

Second source/drain patterns 250 may be connected to the second channel groups CH2. The second source/drain patterns 250 may be connected to the second channel patterns CH21, the fifth channel patterns CH22, and the sixth channel patterns CH23 of the second channel groups CH2.

Gate structures GS may include inner gate structures GS_INT. The inner gate structures GS_INT may include gate electrodes 120 and gate insulating films 130.

In a cross-sectional view such as FIG. 11, the inner gate structures GS_INT may be disposed between pairs of first and third channel patterns CH11 and CH12 spaced apart from each other in the third direction DR3, and between pairs of third and fourth channel patterns CH12 and CH13 spaced apart from each other in the third direction DR3.

In FIG. 12, the gate electrodes 120 may surround the third channel patterns CH12 and the fourth channel patterns CH13. The gate insulating films 130 may be disposed around the peripheries of the third channel patterns CH12 and the peripheries of the fourth channel patterns CH13.

In a cross-sectional view such as FIG. 13, the inner gate structures GS_INT may be disposed between pairs of second and fifth channel patterns CH21 and CH22 spaced apart from each other in the third direction DR3, and between pairs of fifth and sixth channel patterns CH22 and CH23 spaced apart from each other in the third direction DR3.

In FIG. 12, the gate electrodes 120 may surround the fifth channel patterns CH22 and the sixth channel patterns CH23. The gate insulating films 130 may be disposed around the peripheries of the fifth channel patterns CH22 and the peripheries of the sixth channel patterns CH23.

In FIGS. 11 and 12, the first channel patterns CH11 may not contact the first channel isolation pattern 110. The second channel patterns CH21 may not contact the second channel isolation pattern 210. The inner gate structures GS_INT may be disposed between the first channel patterns CH11 and the first channel isolation pattern 110.

In FIGS. 13 and 14, the first channel patterns CH11 may contact the first channel isolation pattern 110. The second channel patterns CH21 may contact the second channel isolation pattern 210. The inner gate structures GS_INT may not be disposed between the first channel patterns CH11 and the first channel isolation pattern 110.

Gate spacers 140 may not be disposed between the pairs of first and third channel patterns CH11 and CH12 spaced apart from each other in the third direction DR3, or between the pairs of third and fourth channel patterns CH12 and CH13 spaced apart from each other in the third direction DR3. In one or more embodiments, inner gate spacers may be disposed between the pairs of first and third channel patterns CH11 and CH12 spaced apart from each other in the third direction DR3, as well as between the pairs of third and fourth channel patterns CH12 and CH13 spaced apart from each other in the third direction DR3.

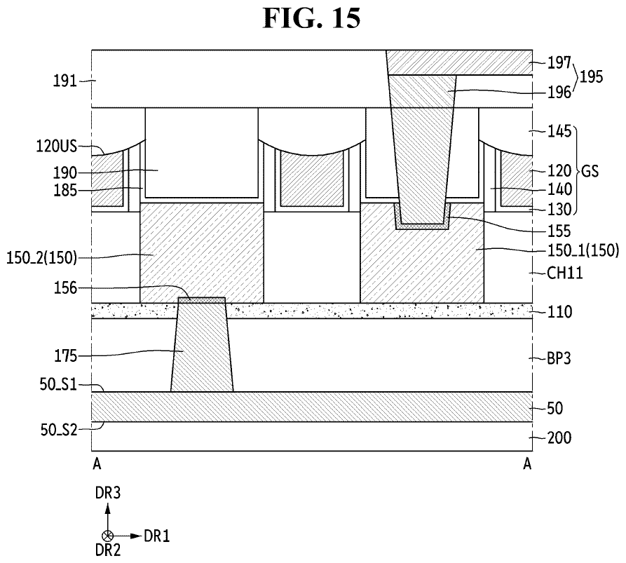

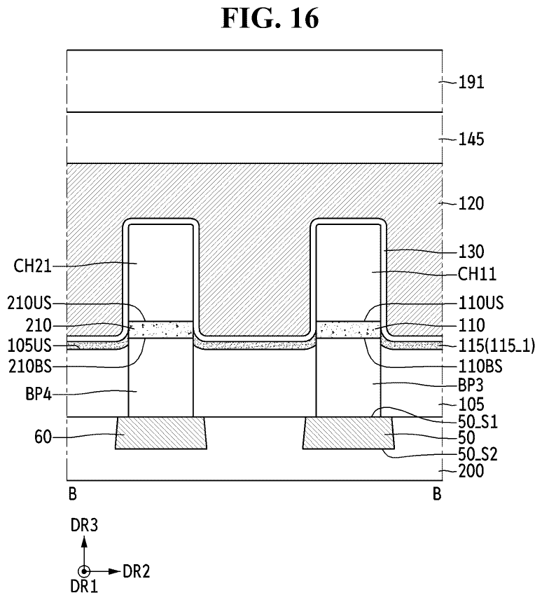

FIGS. 15 and 16 are diagrams illustrating a semiconductor device according to one or more embodiments. For convenience, the embodiments will hereinafter be described, highlighting the differences from the embodiment of FIGS. 1 through 6.

Referring to FIGS. 15 and 16, the semiconductor devices according to one or more embodiments may include a first backside wiring line 50, a second backside wiring line 60, a backside source/drain contact 175, a third protruding pattern BP3, a fourth protruding pattern BP4, a field capping film 115, a first channel isolation pattern 110, a second channel isolation pattern 210, a first channel pattern CH11, a second channel pattern CH21, a gate electrode 120, and a first source/drain pattern 150.

The descriptions for the field capping film 115, the first channel isolation pattern 110, the second channel isolation pattern 210, the first channel pattern CH11, the second channel pattern CH21, the gate electrode 120, and the first source/drain pattern 150 may overlap with the descriptions for their respective counterparts of FIGS. 1 through 6, and thus, the following description will focus on the differences.

A second substrate 200 may include an insulating material. The second substrate 200 may include at least one of silicon oxide, silicon nitride, or silicon oxynitride, but the disclosure is not limited thereto.

The first and second backside wiring lines 50 and 60 may be disposed within the second substrate 200. The first and second backside wiring lines 50 and 60 may each extend in the first direction DR1. The first backside wiring line 50 may be spaced apart from the second backside wiring line 60 in the second direction DR2.

For example, the first and second backside wiring lines 50 and 60 may be power lines supplying power to the semiconductor device according to one or more embodiments. In another example, the first and second backside wiring lines 50 and 60 may be signal lines supplying operation signals to the semiconductor device according to one or more embodiments. In yet another example, one of the first and second backside wiring lines 50 and 60 may be a power line, and the other backside wiring line may be a signal line.

The first backside wiring line 50 may include a first surface 50_S1 and a second surface 50_S2 opposite to each other in the third direction DR3. The second backside wiring line 60 may include a first surface and a second surface opposite to each other in the third direction DR3. The first surfaces 50_S1 of the first and second backside wiring lines 50 and 60 may face the first source/drain pattern 150, the first channel isolation pattern 110, and the second channel isolation pattern 210.

The first and second backside wiring lines 50 and 60 are illustrated as having a trapezoidal cross-sectional shape, but the disclosure is not limited thereto. In one or more embodiments, the first and second backside wiring lines 50 and 60 may have a rectangular cross-sectional shape. The width of the first surface 50_S1 of the first backside wiring line 50 in the second direction DR2 may be smaller than the width of the second surface 50_S2 in the second direction DR2.

For example, the first and second backside wiring lines 50 and 60 may be formed using a damascene process. The first and second backside wiring lines 50 and 60 may be formed by forming trenches extending in the first direction DR1 in the second substrate 200, and filling the trenches with a conductive material.

The first and second backside wiring lines 50 and 60 are illustrated as having a single conductive film structure, but the disclosure is not limited thereto. The first and second backside wiring lines 50 and 60 may include, for example, at least one of metal, conductive metal nitride, conductive metal carbide, conductive metal oxide, conductive metal carbonitride, or a 2D material.

In one or more embodiments, the first and second backside wiring lines 50 and 60 may each extend in the second direction DR2. The first backside wiring line 50 may be spaced apart from the second backside wiring line 60 in the first direction DR1. In this case, the cross-sectional views along lines A-A and B-B of FIG. 11 may differ.

In one or more embodiments, the first and second backside wiring lines 50 and 60 may each include a line portion and a via portion. The line portion of, for example, the first backside wiring line 50 may extend longitudinally in the first direction DR1. The via portion of the first backside wiring line 50 may protrude in the third direction DR3 from the line portion of the first backside wiring line 50. The via portion of the first backside wiring line 50 may protrude toward the backside source/drain contact 175.

The third and fourth protruding patterns BP3 and BP4 may protrude in the third direction DR3 from the second substrate 200. The third and fourth protruding patterns BP3 and BP4 may each extend longitudinally in the first direction DR1. The third protruding pattern BP3 may be spaced apart from the fourth protruding pattern BP4 in the second direction DR2. The third and fourth protruding patterns BP3 and BP4 may be disposed on the first surface 50_S1 of the first backside wiring line 50.

For example, the third and fourth protruding patterns BP3 and BP4 may include an elemental semiconductor material such as Si or Ge. Alternatively, the third and fourth protruding patterns BP3 and BP4 may include a compound semiconductor.

In another example, the third and fourth protruding patterns BP3 and BP4 may include an insulating material. The third and fourth protruding patterns BP3 and BP4 may include at least one of silicon oxide, silicon nitride, or silicon oxynitride. A field insulating film 105 may be disposed on the sidewalls of the third and fourth protruding patterns BP3 and BP4. If the field insulating film 105 and the third and fourth protruding patterns BP3 and BP4 include the same insulating material, the boundaries between the field insulating film 105 and the third and fourth protruding patterns BP3 and BP4 may not be distinguishable.

The first and second channel isolation patterns 110 and 210 may be disposed on the first surface 50_S1 of the first backside wiring line 50. The bottom surfaces 110BS and 210BS of the first and second channel isolation patterns 110 and 210 may face the first and second backside wiring lines 50 and 60.

The first and second backside wiring lines 50 and 60 may be disposed on the bottom surfaces 110BS and 210BS of the first and second channel isolation patterns 110 and 210. A front-side wiring line 197 may be disposed on the upper surfaces 110US and 210US of the first and second channel isolation patterns 110 and 210.

The first channel isolation pattern 110 may contact the third protruding pattern BP3. The second channel isolation pattern 210 may contact the fourth protruding pattern BP4.

The first source/drain pattern 150 may include a first front-side source/drain pattern 150_1 and a first backside source/drain pattern 150_2. The first front-side source/drain pattern 150_1 and the first backside source/drain pattern 150_2 may be disposed on the first surface 50_S1 of the first backside wiring line 50.

The first front-side source/drain pattern 150_1 and the first backside source/drain pattern 150_2 may be spaced apart from each other in the first direction DR1 with the first channel pattern CH11 interposed therebetween.

A first front-side source/drain contact 180 may be connected to the first front-side source/drain pattern 150_1. A first contact silicide film 155 may be disposed between the first front-side source/drain contact 180 and the first front-side source/drain pattern 150_1. For example, the first front-side source/drain pattern 150_1 may not be connected to the first and second backside wiring lines 50 and 60.

A backside source/drain contact 175 may be connected to the first backside source/drain pattern 150_2. For example, the backside source/drain contact 175 may be electrically connected to the first backside source/drain pattern 150_2.

The backside source/drain contact 175 may be disposed between the first backside source/drain pattern 150_2 and the first backside wiring line 50. The backside source/drain contact 175 may overlap with the first backside wiring line 50 and the first backside source/drain pattern 150_2 in the third direction DR3.

The backside source/drain contact 175 connects the first backside wiring line 50 and the first backside source/drain pattern 150_2. The backside source/drain contact 175 may be connected to the first backside wiring line 50. The backside source/drain contact 175 may be connected to the first surface 50_S1 of the first backside wiring line 50.

The backside source/drain contact 175 may be disposed within the third protruding pattern BP3. The backside source/drain contact 175 may extend from the first surface 50_S1 of the first backside wiring line 50 to the first backside source/drain pattern 150_2. The backside source/drain contact 175 may be connected to the first backside source/drain pattern 150_2, passing through the first channel isolation pattern 110.

If the third protruding pattern BP3 includes a semiconductor material, a backside contact insulating liner may be further disposed between the backside source/drain contact 175 and the third protruding pattern BP3. The backside contact insulating liner may include an insulating material.

The backside source/drain contact 175 is illustrated as a single layer, but the disclosure is not limited thereto. For example, the backside source/drain contact 175 may include at least one of a metal, conductive metal nitride, conductive metal carbide, conductive metal oxide, conductive metal carbonitride, a 2D material, or a combination thereof.

A backside contact silicide film 156 may be disposed between the backside source/drain contact 175 and the first backside source/drain pattern 150_2. The backside contact silicide film 156 may include metal silicide.

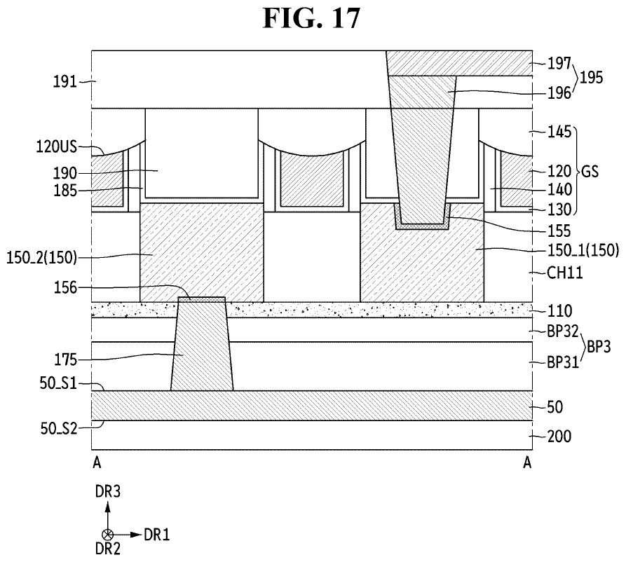

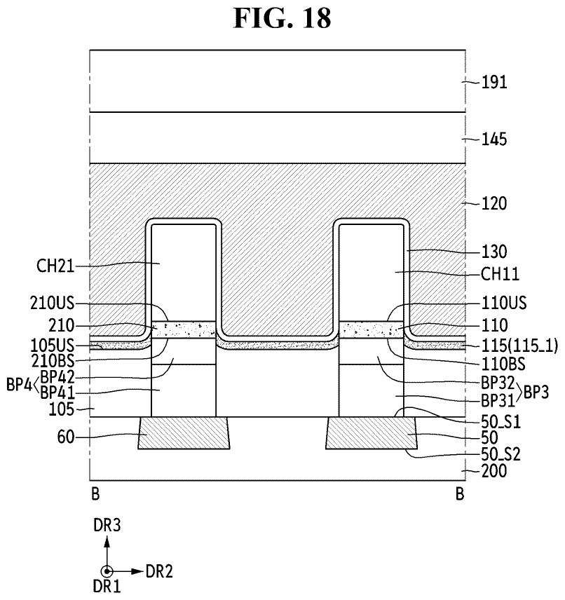

FIGS. 17 and 18 are diagrams illustrating a semiconductor device according to one or more embodiments. For convenience, the embodiments will hereinafter be described, highlighting the differences from the embodiment of FIGS. 15 and 16.

Referring to FIGS. 17 and 18, in the semiconductor devices according to one or more embodiments, a third protruding pattern BP3 may include a third lower protruding pattern BP31 and a third upper protruding pattern BP32.

A fourth protruding pattern BP4 may include a fourth lower protruding pattern BP41 and a fourth upper protruding pattern BP42.

The third upper protruding pattern BP32 may contact a first channel isolation pattern 110. The third lower protruding pattern BP31 may be disposed between the third upper protruding pattern BP32 and a first backside wiring line 50.

The fourth upper protruding pattern BP42 may contact a second channel isolation pattern 210. The fourth lower protruding pattern BP41 may be disposed between the fourth upper protruding pattern BP42 and a second backside wiring line 60.

The third and fourth lower protruding patterns BP31 and BP41 may include an insulating material. The third and fourth upper protruding patterns BP32 and BP42 may include a semiconductor material.

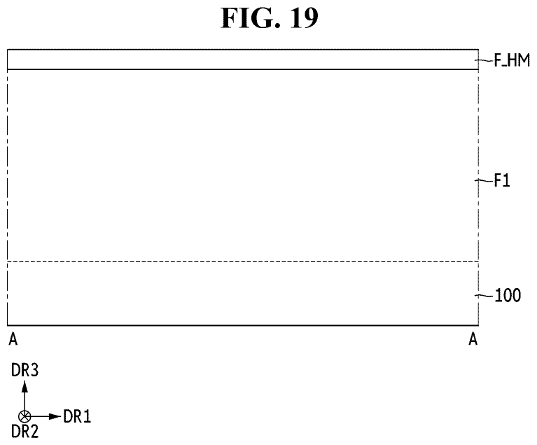

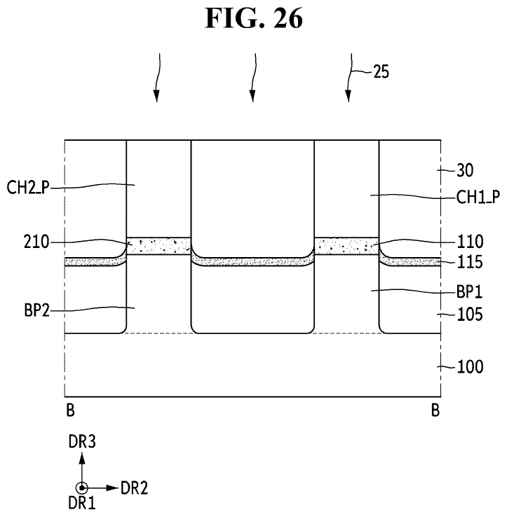

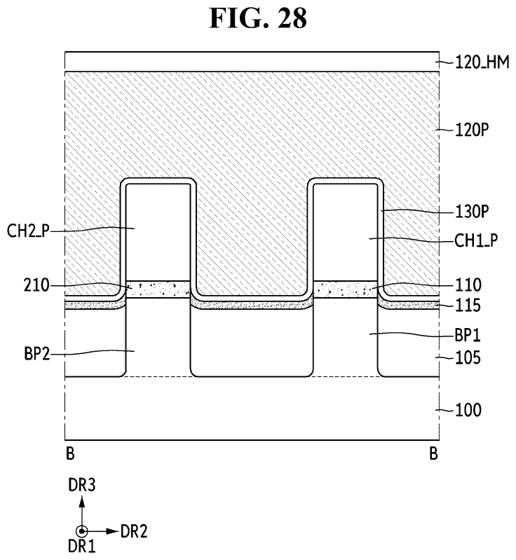

FIGS. 19 through 32 are diagrams illustrating intermediate operations of a method for fabricating a semiconductor device according to one or more embodiments.

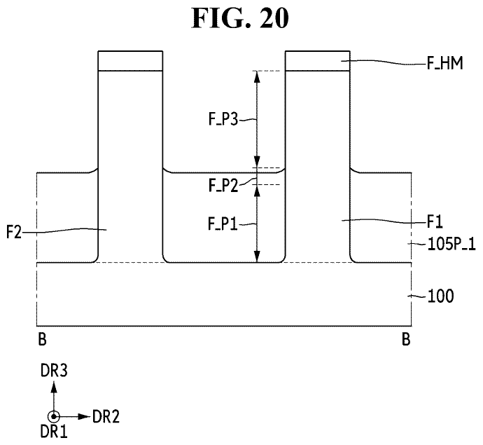

Referring to FIGS. 19 and 20, a first fin-shaped pattern F1 and a second fin-shaped pattern F2 may be formed on a first substrate 100.

The first and second fin-shaped patterns F1 and F2 may extend in the first direction DR1. The first fin-shaped pattern F1 may be spaced apart from the second fin-shaped pattern F2 in the second direction DR2.

A fin hard mask F_HM may be formed on the first and second fin-shaped patterns F1 and F2. The fin hard mask F_HM may be at least part of a mask pattern used to form the first and second fin-shaped patterns F1 and F2. For example, the fin hard mask F_HM may include silicon nitride.

The first and second fin-shaped patterns F1 and F2 may each include a first portion F_P1, a second portion F_P2, and a third portion F_P3. The first portions F_P1 of the first and second fin-shaped patterns F1 and F2 may be directly connected to the first substrate 100. The second portion F_P2 of the first fin-shaped pattern F1 may be disposed between the first portion F_P1 and the third portion F_P3 of the first fin-shaped pattern F1. Similarly, the second portion F_P2 of the second fin-shaped pattern F2 may be disposed between the first portion F_P1 and the third portion F_P3 of the second fin-shaped pattern F2.

Thereafter, a first pre-field insulating film 105P_1 may be formed on the first substrate 100. The first pre-field insulating film 105P_1 may cover portions of the sidewalls of the first fin-shaped pattern F1 and portions of the sidewalls of the second fin-shaped pattern F2. For example, the first pre-field insulating film 105P_1 may cover the sidewalls of the first portions F_P1 of the first fin-shaped pattern F1, the sidewalls of the second portions F_P2 of the first fin-shaped pattern F1, the sidewalls of the first portions F_P1 of the second fin-shaped pattern F2, and the sidewalls of the second portions F_P2 of the second fin-shaped pattern F2.

The sidewalls of the third portion F_P3 of the first fin-shaped pattern F2 and the sidewalls of the third portions F_P3 of the second fin-shaped pattern F2 may be exposed.

The first pre-field insulating film 105P_1 may include, for example, silicon oxide.

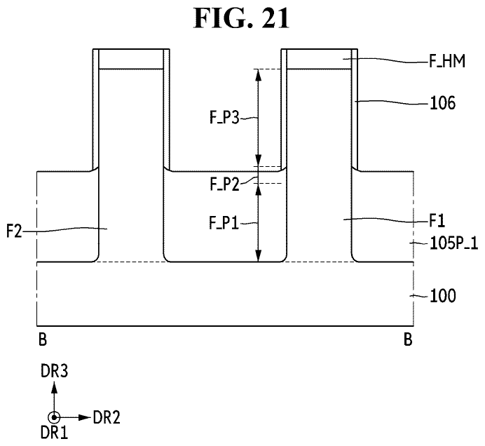

Referring to FIG. 21, fin protection spacers 106 may be formed on the first pre-field insulating film 105P_1.

The fin protection spacers 106 may extend along the sidewalls of the third portion F_P3 of the first fin-shaped pattern F2 and the sidewalls of the third portions F_P3 of the second fin-shaped pattern F2. The fin protection spacers 106 may also be formed along the sidewalls of the fin hard mask F_HM. The fin protection spacers 106 may include a material with an etching selectivity with respect to silicon oxide, silicon nitride, and silicon oxynitride.

Specifically, a fin protection spacer film may be formed along the upper surface of the first pre-field insulating film 105P_1, the sidewalls of the third portion F_P3 of the first fin-shaped pattern F2, and the sidewalls of the third portions F_P3 of the second fin-shaped pattern F2. The fin protection spacer film may be formed along the sidewalls and upper surface of the fin hard mask F_HM. By anisotropically etching the fin protection spacer film, the fin protection spacers 106 may be formed.

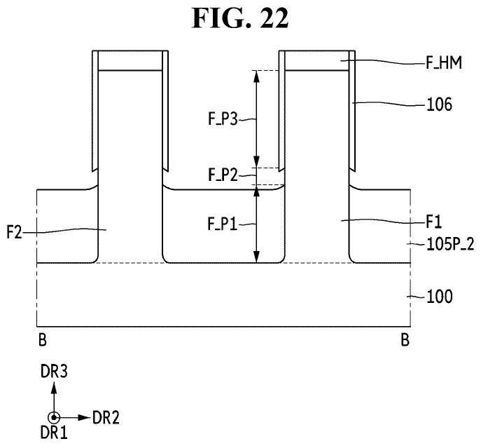

Referring to FIGS. 21 and 22, a second pre-field insulating film 105P_2 may be formed on the first substrate 100 by removing part of the first pre-field insulating film 105P_1.

The second pre-field insulating film 105P_2 may cover the sidewalls of the first portion F_P1 of the first fin-shaped pattern F1 and the sidewalls of the first portion F_P1 of the second fin-shaped pattern F2. The second pre-field insulating film 105P_2 may expose the sidewalls of the second portion F_P2 of the first fin-shaped pattern F1 and the sidewalls of the second portion F_P2 of the second fin-shaped pattern F2.

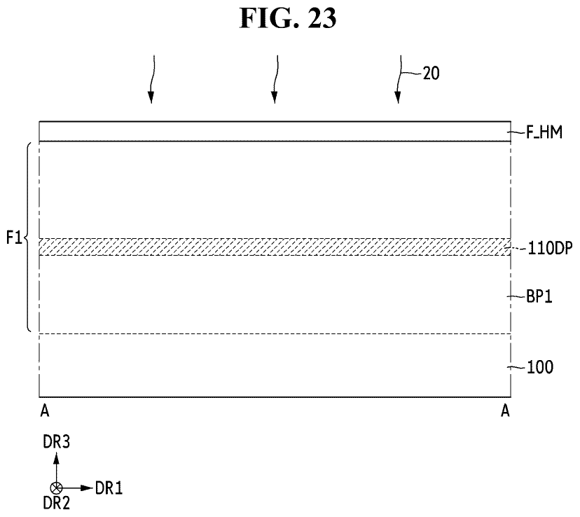

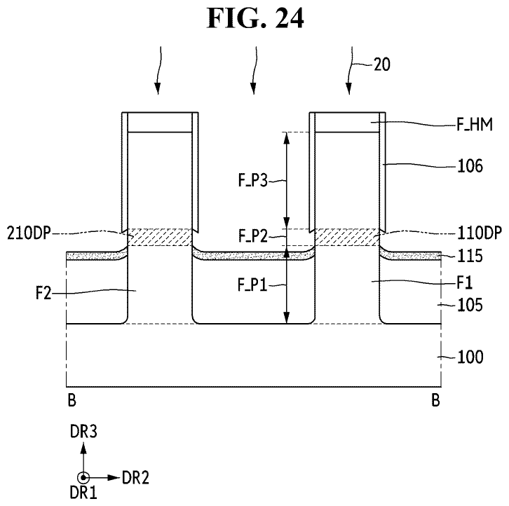

Referring to FIGS. 23 and 24, nitrogen (N₂) may be implanted into the first and second fin-shaped patterns F1 and F2 through a plasma process 20.

The N₂ may be implanted into the first and second fin-shaped patterns F1 and F2 through the exposed sidewalls of the second portions F_P2 of the first and second fin-shaped patterns F1 and F2. For example, the N₂ may be implanted into the second portions F_P2 of the first and second fin-shaped patterns F1 and F2. Consequently, first and second nitrogen implantation regions 110DP and 210DP may be formed in the first and second fin-shaped patterns F1 and F2, respectively.

During the plasma process 20, the N₂ may also be implanted into the second pre-field insulating film 105P_2. For example, the N₂ may be implanted into the upper portion of the second pre-field insulating film 105P_2. As the N₂ is implanted into the second pre-field insulating film 105P_2, a field insulating film 105 and a nitrogen (N₂)-implanted field capping film 115 may be formed on the first substrate 100. The field insulating film 105 may cover the sidewalls of the first portion F_P1 of the first fin-shaped pattern F1 and the sidewalls of the first portion F_P1 of the second fin-type pattern F2.

Referring to FIGS. 23 through 26, after the formation of the first and second nitrogen implantation regions 110DP and 210DP, the fin protection spacers 106 may be removed.

Thereafter, a capping field insulating film 30 may be formed on the nitrogen-implanted field capping film 115. The capping field insulating film 30 may include, for example, silicon oxide. During the formation of the capping field insulating film 30, the fin hard mask F_HM may be removed.

Thereafter, using the N₂ implanted into the first fin-shaped pattern F1, the second portion F_P2 of the first fin-shaped pattern F1 may be nitrided. Specifically, through a heat treatment process 25, the silicon and nitrogen in the first nitrogen implantation region 110DP may be transformed into silicon nitride. Consequently, a first channel isolation pattern 110 may be formed.

Similarly, using the nitrogen implanted into the second fin-shaped pattern F2, the second portion F_P2 of the second fin-shaped pattern F2 may be nitrided. Consequently, a second channel isolation pattern 210 may be formed.

As the first channel separation pattern 110 is formed, the first protruding pattern BP1, the first channel isolation pattern 110, and the first pre-channel film CH1_P may be formed on the first substrate 100. Similarly, as the second channel separation pattern 210 is formed, the second protruding pattern BP2, the second channel isolation pattern 210, and the second pre-channel film CH2_P may be formed on the first substrate 100.

During the formation of the first and second channel isolation patterns 110 and 210, the nitrogen-implanted field capping film 115 may be transformed into a field capping film 115 containing silicon oxynitride.

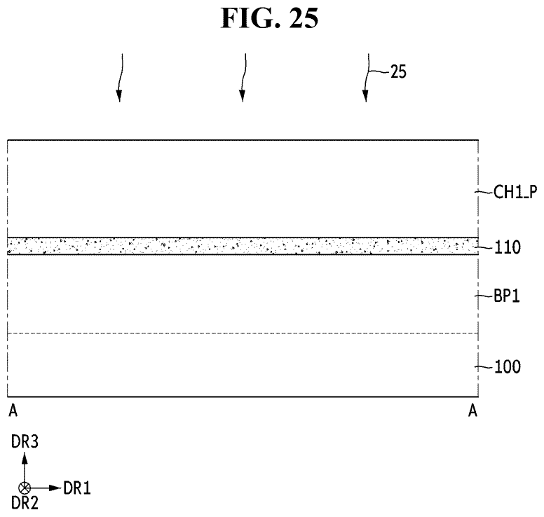

Referring to FIGS. 25 through 28, the capping field insulating film 30 may be removed.

After the removal of the capping field insulating film 30, a dummy gate structure may be formed on the field capping film 115. The dummy gate structure may be formed on the first and second pre-channel films CH1_P and CH2_P.

The dummy gate structure may include a dummy gate insulating film 130P, a dummy gate electrode 120P, and a dummy gate capping film 120_HM. The dummy gate insulating film 130P may include, for example, silicon oxide, but the disclosure is not limited thereto. The dummy gate electrode 120P may include, for example, polysilicon, but the disclosure is not limited thereto. The dummy gate capping film 120_HM may include, for example, silicon nitride, but the disclosure is not limited thereto.

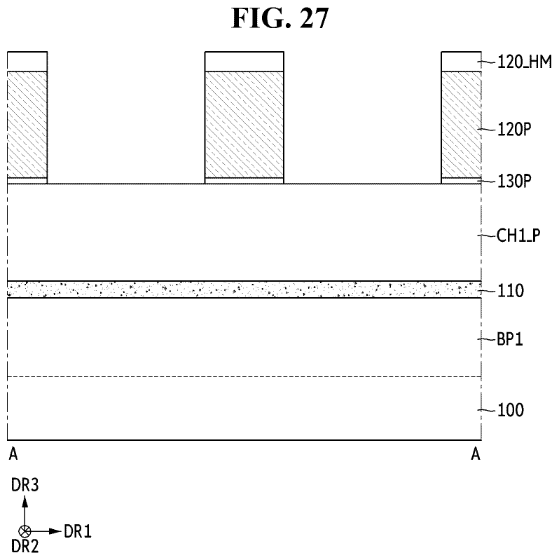

Referring to FIGS. 27 through 29, gate spacers 140 may be formed on the sidewalls of the dummy gate electrode 120P.

During the formation of the gate spacers 140, source/drain recesses 150R may be formed in the first pre-channel film CH1_P using the gate spacers 140 and the dummy gate electrode 120P as a mask. The source/drain recesses 150R may divide the first pre-channel film CH1_P into a plurality of first channel patterns CH11. In a cross-sectional view, the bottom surfaces of the source/drain recesses 150R may be defined by the first channel isolation pattern 110, and the sidewalls of the source/drain recesses 150R may be defined by the first channel patterns CH11.

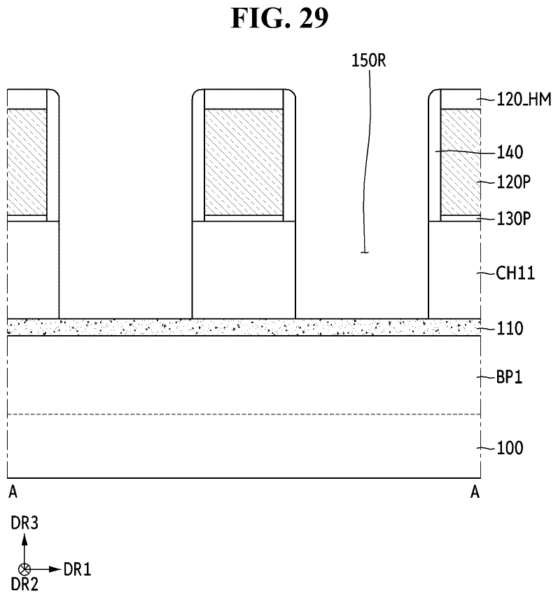

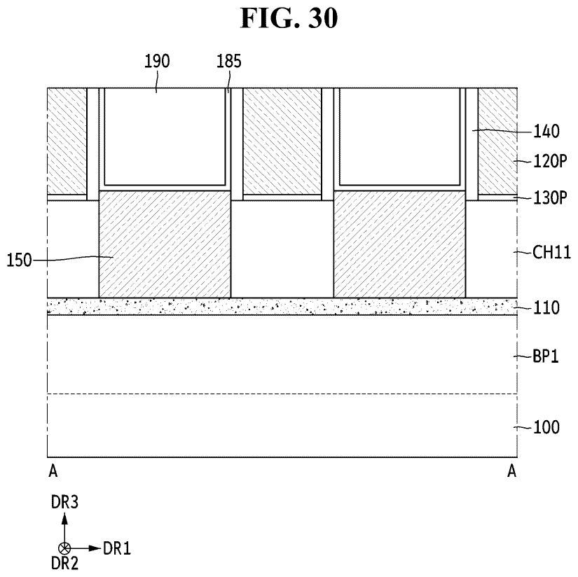

Referring to FIGS. 29 and 30, first source/drain patterns 150 may be formed on the first channel isolation pattern 110.

The first source/drain patterns 150 may fill the source/drain recesses 150R. The first source/drain patterns 150 are connected to the first channel patterns CH11.

A source/drain etching stop film 185 and a first interlayer insulating film 190 may be formed on each of the first source/drain patterns 150.

Thereafter, the upper surface of the dummy gate electrode 120P is exposed by removing portions of the first interlayer insulating film 190 and source/drain etching stop film 185, as well as the dummy gate capping film 120_HM. During the exposure of the upper surface of the dummy gate electrode 120P, portions of the gate spacers 140 may be removed.

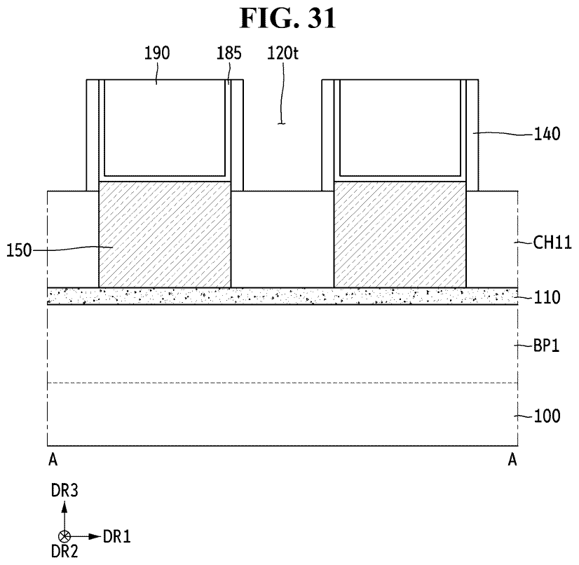

Referring to FIGS. 30 and 31, the first channel patterns CH11 may be exposed by removing the dummy gate insulating film 130P and the dummy gate electrode 120P.

As a result, gate trenches 120t may be formed.

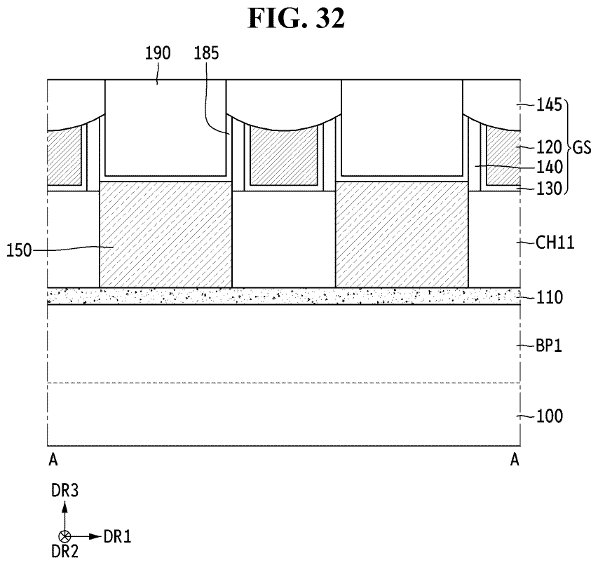

Referring to FIGS. 31 and 32, a gate insulating film 130 and a gate electrode 120 may be formed in each of the gate trenches 120t.

Additionally, a gate capping pattern 145 may be formed on the gate electrode 120.

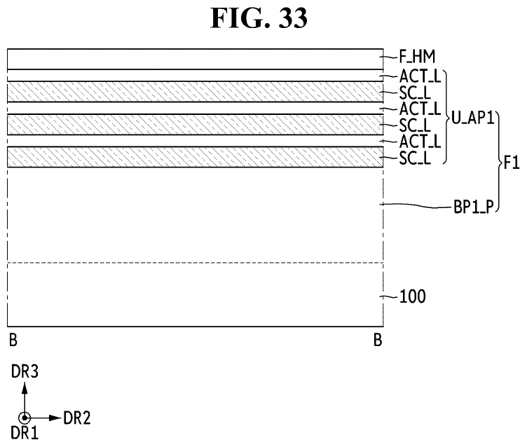

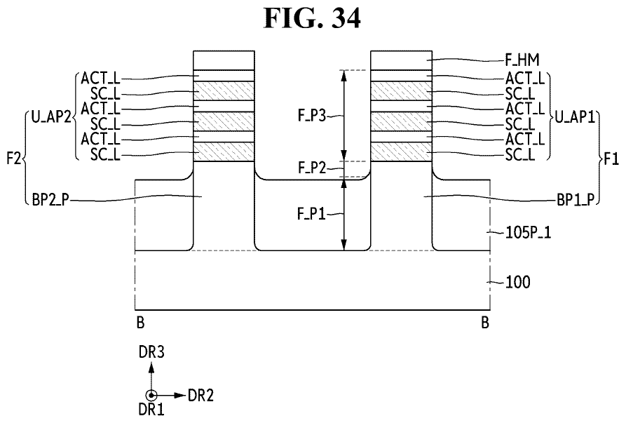

FIGS. 33 and 34 are diagrams illustrating intermediate operations of a method for fabricating a semiconductor device according to one or more embodiments. For convenience, the embodiment of FIGS. 33 and 34 will hereinafter be described, highlighting the differences from the embodiment of FIGS. 19 through 32.

Referring to FIGS. 33 and 34, a first fin-shaped pattern F1 and a second fin-shaped pattern F2 may be formed on a first substrate 100.

The first fin-shaped pattern F1 may include a first pre-protruding pattern BP1_P and a first upper pattern structure U_AP1. The second fin-shaped pattern F2 may include a second pre-protruding pattern BP2_P and a second upper pattern structure U_AP2.

The first and second upper pattern structures U_AP1 and U_AP2 may each include sacrificial patterns SC_L and active patterns ACT_L alternately arranged in the third direction DR3. For example, the sacrificial patterns SC_L may each include an SiGe film, and the active patterns ACT_L may each include an Si film.

A first portion F_P1 of the first fin-shaped pattern F1 may include a first pre-protruding pattern BP1_P, and a first portion F_P1 of the second fin-shaped pattern F2 may include a second pre-protruding pattern BP2_P.

A second portion F_P2 and a third portion F_P3 of the first fin-shaped pattern F1 may include the first upper pattern structure U_AP1. A second portion F_P2 and a third portion F_P3 of the second fin-shaped pattern F2 may include the second upper pattern structure U_AP2.

In one or more embodiments, the second and third portions F_P2 and F_P3 of the first fin-shaped pattern F1 may include part of the first pre-protruding pattern BP1_P. Similarly, the second and third portions F_P2 and F_P3 of the second fin-shaped pattern F2 may include part of the second pre-protruding pattern BP2_P.

Thereafter, a first pre-field insulating film 105P_1 may be formed on the first substrate 100.

Thereafter, first and second channel isolation patterns 110 and 210 may be formed using the method described with reference to FIGS. 20 through 32. However, during the formation of the gate trenches 120t in FIG. 31, the sacrificial patterns SC_L included in each of the first and second upper pattern structures U_AP1 and U_AP2 may be removed. Consequently, a first channel group (CH1 in FIGS. 12 and 14) and a second channel group (CH2 in FIGS. 12 and 14) may be formed.

In concluding the detailed description, those skilled in the art will appreciate that many variations and modifications may be made to the one or more embodiments disclosed herein without substantially departing from the principles of the present disclosure. Therefore, the one or more embodiments of the disclosure are used in a generic and descriptive sense only and not for purposes of limitation.

What is claimed is:

1. A semiconductor device comprising:
a protruding pattern extending in a first direction;
a first channel pattern spaced apart from the protruding pattern in a second direction;
a channel isolation pattern between the protruding pattern and the first channel pattern, wherein the channel isolation pattern comprises silicon nitride and is in contact with the protruding pattern;
a field insulating film on a sidewall of the protruding pattern;
a gate electrode on an upper surface of the field insulating film and extending in a third direction;
a source/drain pattern on at least one side of the gate electrode and connected to the first channel pattern; and
a field capping film between the upper surface of the field insulating film and a bottom surface of the gate electrode, the field capping film comprising silicon (Si) and nitrogen (N).

2. The semiconductor device of claim 1, further comprising:
a gate spacer on a sidewall of the gate electrode,
wherein the field capping film is between a bottom surface of the gate spacer and the upper surface of the field insulating film.

3. The semiconductor device of claim 1, wherein the field capping film comprises a first region and a second region, alternately arranged in the first direction,
wherein the first region of the field capping film is between the upper surface of the field insulating film and the bottom surface of the gate electrode, and
wherein the second region of the field capping film is on a side of the source/drain pattern.

4. The semiconductor device of claim 3, wherein a thickness of the first region of the field capping film is equal to or greater than a thickness of the second region of the field capping film.

5. The semiconductor device of claim 1, wherein the first channel pattern is in contact with the channel isolation pattern.

6. The semiconductor device of claim 5, further comprising:
a second channel pattern on the first channel pattern,
wherein in a cross-sectional view, the gate electrode is between the first channel pattern and the second channel pattern.

7. The semiconductor device of claim 1, further comprising:
a second channel pattern on the first channel pattern,
wherein in a cross-sectional view, the gate electrode is between the first channel pattern and the channel isolation pattern, and the gate electrode is between the first channel pattern and the second channel pattern.

8. The semiconductor device of claim 1, wherein the channel isolation pattern is between the source/drain pattern and the protruding pattern.

9. The semiconductor device of claim 1, wherein the field capping film comprises silicon oxynitride.

10. The semiconductor device of claim 9, wherein a concentration of nitrogen in the field capping film decreases as a distance from the bottom surface of the gate electrode increases.

11. A semiconductor device comprising:
a field insulating film;
a field capping film on an upper surface of the field insulating film, the field capping film comprising silicon oxynitride;
a channel isolation pattern extending in a first direction on the field insulating film, wherein the channel isolation pattern comprises silicon nitride and is in contact with the field capping film;
a first channel pattern on the channel isolation pattern and overlapping with the channel isolation pattern in a second direction;
a source/drain pattern on the channel isolation pattern and connected to the first channel pattern; and
a gate structure on the field capping film, wherein the gate structure extends in a third direction and comprises a gate electrode and a gate spacer, and wherein the gate structure is on a side of the source/drain pattern.

12. The semiconductor device of claim 11, wherein the field capping film comprises a first region and a second region,
wherein the first region of the field capping film is between the upper surface of the field insulating film and a bottom surface of the gate electrode,
wherein the second region of the field capping film is between the gate structure and a second gate structure adjacent to the gate structure in the first direction; and
wherein a thickness of the first region of the field capping film is equal to or greater than a thickness of the second region of the field capping film.

13. The semiconductor device of claim 11, further comprising:
a protruding pattern extending in the first direction and overlapping with the channel isolation pattern in the second direction,
wherein the channel isolation pattern is between the protruding pattern and the first channel pattern, and
wherein the protruding pattern is in contact with the channel isolation pattern.

14. The semiconductor device of claim 13, wherein the field insulating film is on a sidewall of the protruding pattern.

15. The semiconductor device of claim 11, wherein the first channel pattern is in contact with the channel isolation pattern.

16. The semiconductor device of claim 15, further comprising:
a second channel pattern on the first channel pattern,
wherein the second channel pattern overlaps with the first channel pattern in the second direction, and
wherein in a cross-sectional view, the gate electrode is between the first channel pattern and the second channel pattern.

17. The semiconductor device of claim 11, further comprising:
a second channel pattern on the first channel pattern,
wherein the second channel pattern overlaps with the first channel pattern in the second direction, and
wherein in a cross-sectional view, the gate electrode is between the first channel pattern and the channel isolation pattern, and the gate electrode is between the first channel pattern and the second channel pattern.

18. A semiconductor device comprising:
a protruding pattern extending in a first direction;
a first channel pattern on the protruding pattern and overlapping with the protruding pattern in a second direction;
a channel isolation pattern between the protruding pattern and the first channel pattern, the channel isolation pattern comprising silicon nitride and extending in the first direction along an upper surface of the protruding pattern;
a field insulating film on a sidewall of the protruding pattern, the field insulating film comprising silicon oxide;
a source/drain pattern on the channel isolation pattern and connected to the first channel pattern;
a gate electrode on an upper surface of the field insulating film, wherein the gate electrode extends in a third direction and is on a side of the source/drain pattern;
a gate spacer on a sidewall of the gate electrode; and
a field capping film between the field insulating film and the gate electrode,
wherein the field capping film is between the gate spacer and the field insulating film, is in contact with the channel isolation pattern, and comprises silicon oxynitride.

19. The semiconductor device of claim 18, further comprising:
a second channel pattern on the first channel pattern and overlapping with the first channel pattern in the second direction,
wherein the gate electrode at least partially surrounds the second channel pattern.

20. The semiconductor device of claim 18, wherein the channel isolation pattern is in contact with both the protruding pattern and the first channel pattern.
